(19) United States
(12) Patent Application Publication
(10) Pub. No.: US 2024/0153793 A1
(43) Pub. Date: May 9, 2024

(54) PLATE GAS HEATER

(71) Applicant: Yield Engineering Systems, Inc., Fremont, CA (US)

(72) Inventors: Craig W McCoy, San Jose, CA (US); Greg Pizzo, Morgan Hill, CA (US); Christopher Lane, Los Gatos, CA (US)

(73) Assignee: Yield Engineering Systems, Inc., Fremont, CA (US)

(21) Appl. No.: 18/053,980

(22) Filed: Nov. 9, 2022

(51) Int. Cl. H01L 21/67; F24C 3/08; F24C 15/10; H05B 3/26

(52) U.S. Cl. CPC H01L 21/67103; F24C 3/087; F24C 15/102; H05B 3/26

(57) ABSTRACT

A heating unit includes a base plate and a cover plate. A passage extends through base plate such that a conduit is defined between base plate and cover plate. A first set of heaters is disposed on a side of base plate opposite passage and a second set of heaters is disposed on a side of cover plate opposite passage.

### TECHNICAL FIELD

The present disclosure relates to a process gas heater.

### BACKGROUND

A continuing trend in semiconductor technology is the formation of integrated circuit chips having more and faster circuits thereon. Processing of semiconductor devices includes many fabrication steps (e.g., oxidation, diffusion, annealing, chemical vapor deposition (CVD), atomic layer deposition (ALD), etc.). Many of these steps involve high temperature processing. During some high temperature processing steps, heating units (or heaters) are used to heat process gases used in the fabrication step. Different types of process gas heaters are used in the art for this purpose. Many such gas heaters have characteristics that limit their use. For example, some heaters have limited upper temperature capability. In some heaters, heating rods are difficult to replace, etc. Process gas heaters of the current disclosure may reduce or eliminate one or more of the above-described limitations.

### SUMMARY

Several embodiments of heaters are disclosed. In one embodiment, a heating unit includes a base plate having a first side and a second side, disposed opposite the first side. The base plate can include a passage formed therein and extending therethrough. The passage can be open on the first side and closed on the second side. The heating unit may also include a cover plate having a third side and a fourth side, disposed opposite the third side. The cover plate may be disposed on the base plate such that the third side and the passage together define a conduit extending through or into the base plate. A first set of heaters may be disposed on the second side of the base plate, and a second set of heaters may be disposed on the fourth side of the cover plate. The first set and second sets of heaters may each include one or more heaters.

In another embodiment, a heating unit includes a base plate having a first side and a second side, disposed opposite the first side, and a cover plate having a third side and a fourth side, disposed opposite the third side. The third side of the cover plate may be disposed on the first side of the base plate. A gas-flow conduit may be defined by the base plate and the third side of the cover plate. A gas inlet may be fluidly coupled to a first end of the gas-flow conduit and a gas outlet may be fluidly coupled to a second end of the gas-flow conduit. The gas inlet may be configured to admit a gas into the gas-flow conduit, and the gas outlet may be configured to discharge the gas from the gas-flow conduit. A first set of heaters may be configured to heat the second side of the base plate and a second set of heaters may be configured to heat the fourth side of the cover plate. The first set of heaters and the second set of heaters may both include one or more heaters.

### BRIEF DESCRIPTION OF THE DRAWINGS

The accompanying drawings, which are incorporated herein and constitute a part of this disclosure, illustrate exemplary embodiments and, together with the description, are used to explain the disclosed principles. In these drawings, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure of the various described embodiments. Details of well-known components or features may be omitted to avoid obscuring other features, since these omitted features are well-known to those of ordinary skill in the art. Further, elements in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing dimensions or proportional relationships between different features in a figure. Additionally, even if it is not expressly mentioned, aspects described with reference to one embodiment or figure may also be applicable to, and may be used with, other embodiments or figures.

FIGS. 1A and 1B illustrate an exemplary processing oven of the present disclosure;

FIGS. 2A and 2B illustrate exemplary heaters of the current disclosure that may be used with the processing oven of FIG. 1A;

FIG. 3 is an exploded view of a heater of the current disclosure;

FIGS. 4A-4D illustrate exemplary configurations of base plates of a heater of the current disclosure;

FIGS. 5A-5B illustrate exemplary configurations of cover plates of a heater of the current disclosure;

FIGS. 6A-6C are schematic illustrations of exemplary heaters of the current disclosure;

FIGS. 7A-7E are schematic illustrations of other exemplary heaters of the current disclosure; and

FIGS. 8A-8B illustrate the use of exemplary heaters of the current disclosure.

### DETAILED DESCRIPTION

All relative terms such as “about,” “substantially,” “approximately,” etc., indicate a possible variation of ±10% (unless noted otherwise or another degree of variation is specified). For example, a feature (e.g., slot, etc.) disclosed as being about “t” units wide (or length, thickness, depth, etc.) may vary in width from (t−0.1t) to (t+0.1t) units. Similarly, a temperature within a range of about 100-150° C. can be any temperature between (100-10%) and (150+10%). In some cases, the specification also provides context to some of the relative terms used. For example, a structure (e.g., groove) described as being substantially semicircular or rectangular in cross-sectional shape may deviate (e.g., 10% deviation, etc.) from being perfectly semicircular or rectangular. Further, a range described as varying from, or between, 5 to 10 (5-10), includes the endpoints (i.e., 5 and 10).

Unless otherwise defined, all terms of art, notations, and other scientific terms or terminology used herein have the same meaning as commonly understood by persons of ordinary skill in the art to which this disclosure belongs. Some components, structures, and/or processes described or referenced herein are well understood and commonly employed using conventional methodology by those skilled in the art. These components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in references incorporated by reference. None of the references described or referenced herein is admitted as prior art relative to the current disclosure.

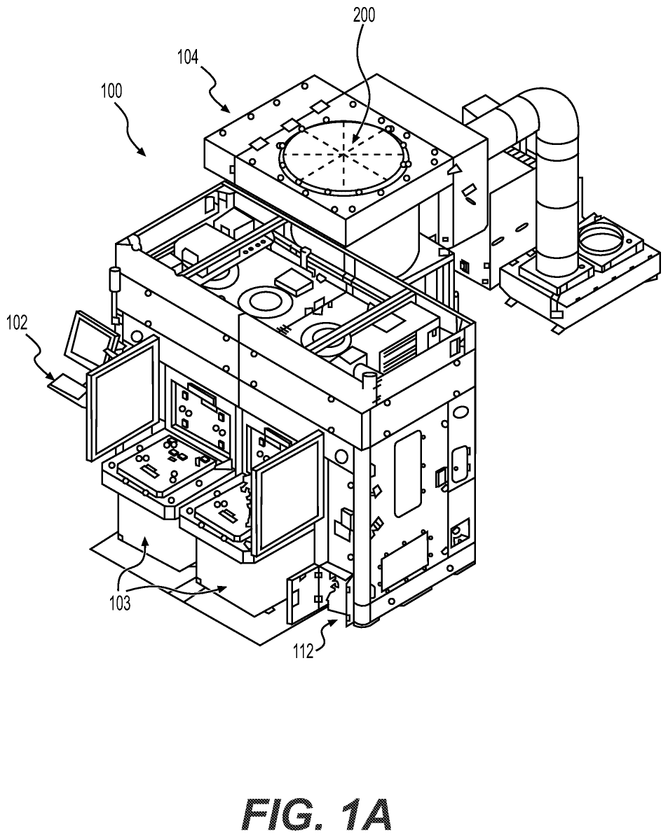

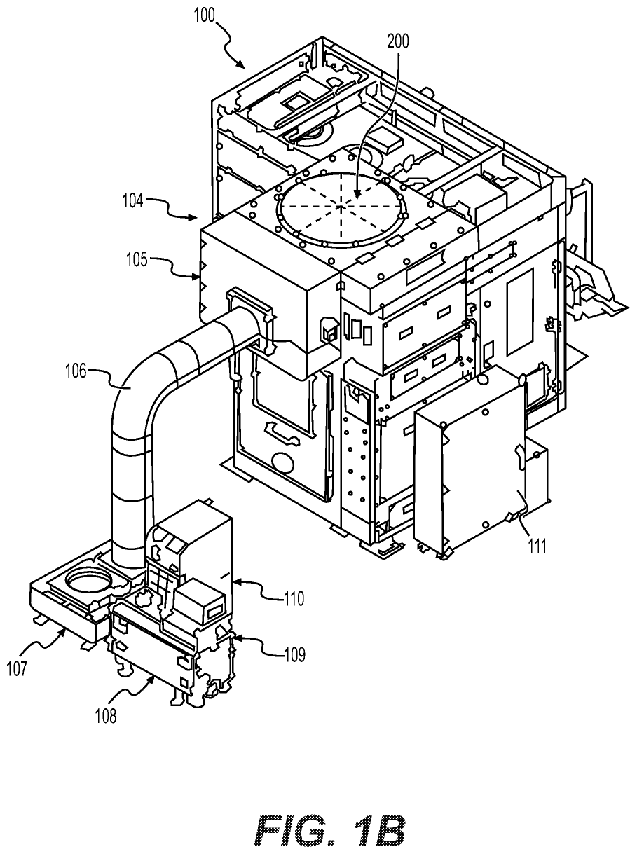

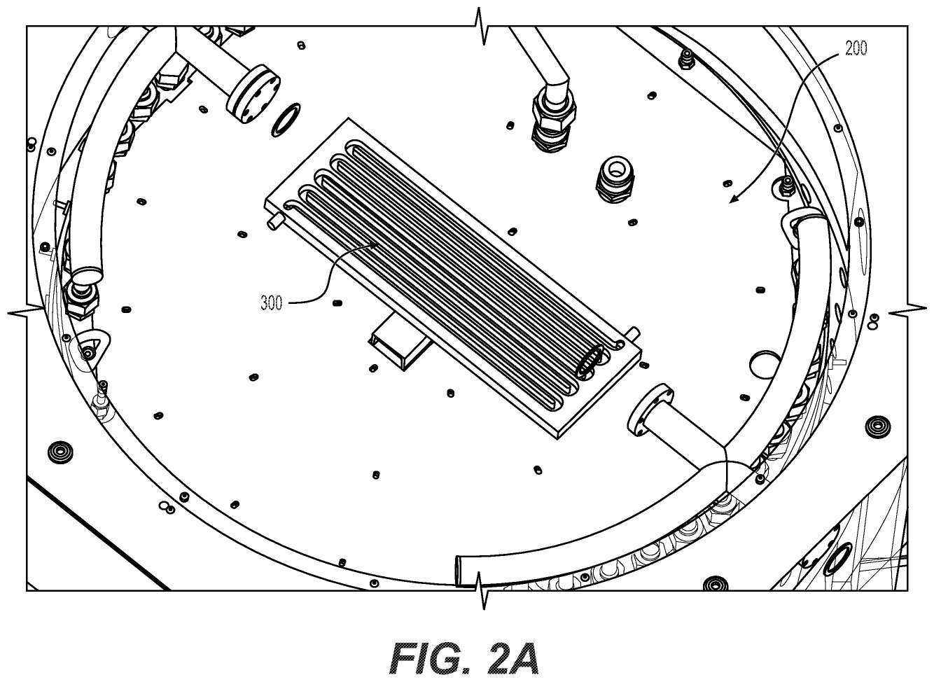

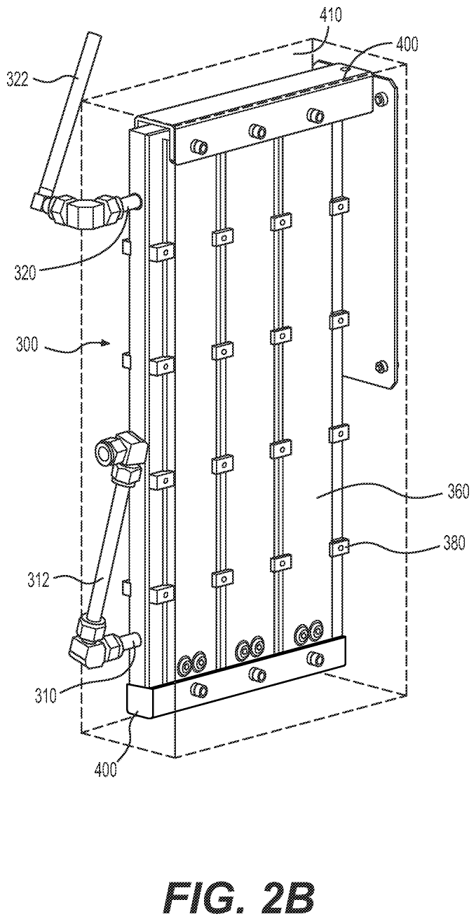

The discussion below describes exemplary heaters of the current disclosure used in a semiconductor processing application. It should be noted that this is not a limitation and heaters of the current disclosure can be used to heat gases in any application. FIGS. 1A and 1B illustrate different views of an exemplary processing oven 100 used in semiconductor processing. An operator works at the GUI 102 (graphic user interface) on an Equipment Front End Module (EFEM 101) where substrates are introduced into oven 100 via attached load ports 103. Oven 100 includes process module 104 with processing chamber assembly (or processing chamber 200) (see FIG. 2). Vacuum pump 108 is connected to processing chamber 200 via fore line (not shown). Duct interface 105 controls air flow to processing chamber 200 from duct 106 and blower 107. Oxygen analyzer 109 connected to pump 108 exhaust is used to monitor the concentration of oxygen in processing chamber 200. Chiller 110 supplies cooling water to pump 108, and power module 111 supplies electric power to oven 100. Depending upon the application, one or more process gases may be directed into oven 100 through facilities panel 112. For example, an inert gas (e.g., nitrogen, argon, etc.) and/or a reactant gas (e.g., formic acid vapor, etc.) may be supplied to processing chamber 200 via panel 112. In some embodiments, one or more gas heaters may be used to heat the process gases before they are discharged into processing chamber 200.

FIGS. 2A and 2B illustrate an exemplary gas heater 300 that may be used to heat process gas directed oven 200. Depending upon the application, heater 300 may be configured to heat process gas at different flow rates to different temperatures. For example, in some embodiments, the heater 300 may be configured to heat nitrogen gas flowing at a rate of (for example) about 1000 standard liter per minute (SLM) to a temperature of (for example) about 650° C. It should be noted that although FIG. 2A illustrates heater 300 as being coupled to processing chamber 200 of oven 100, this is only exemplary. In general, heater 300 may be a stand-alone unit or may be coupled to any structure (e.g., of oven 100) upstream (fluidly) of processing chamber 200. In some embodiments, bracket 400 may mechanically couple heater 300 to the structure. FIG. 2B illustrates heater 300 connected to structure 410 using brackets 400. In some embodiments, structure 410 may be wall of processing chamber 200 or another wall of oven 100. Heater 300 includes gas inlet 310 configured to direct a gas (e.g., nitrogen gas) into heater 300 and gas outlet 320 configured to direct the gas (e.g., heated gas) out of heater 300. Inlet conduit(s) 312 fluidly couples gas inlet 310 to gas source (e.g., gas tank, shop gas supply, etc.) and outlet conduit(s) 322 fluidly couples gas outlet 320 to processing chamber 200. It should be noted that in embodiments where heaters of the current disclosure are used to heat a gas used in another application, outlet conduits 322 will direct heated gas from gas outlet 320 to the desired destination. Gas inlet 310 and gas outlet 320 may include any type of fluid coupling(s) configured to direct the gas into and out of heater 300 in a suitable manner (e.g., without leaks, etc.). To minimize package size and to enable heater to be arranged in the confines of oven 100, heater 300 may be plate-type heater. In other words, heater 300 may have a planar structure and may be configured to be coupled to wall of processing chamber 200 (or another suitable surface of oven 100) such that heated gas exiting via outlet 320 of heater 300 can be delivered to processing chamber 200 without substantial heat loss.

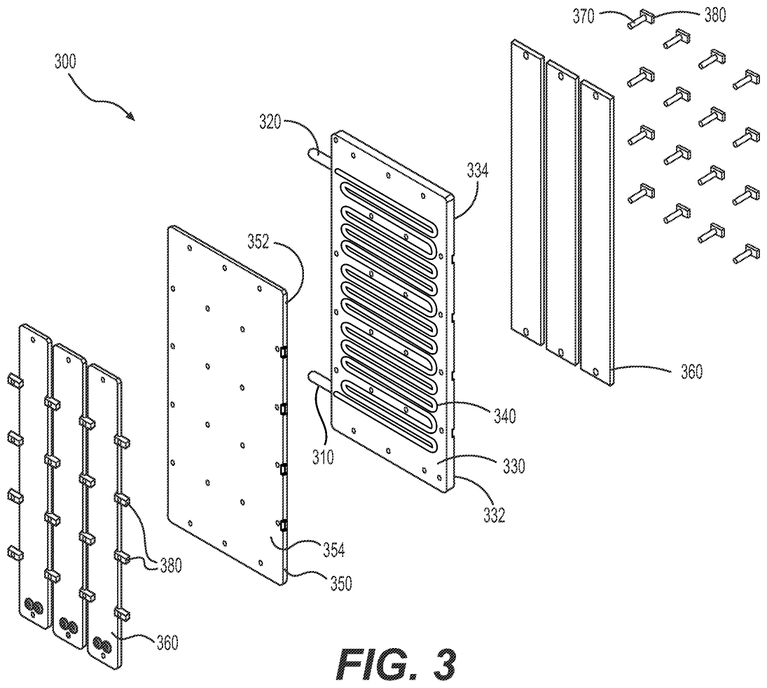

FIG. 3 is an exploded view of an embodiment of heater 300. Heater 300 may have base plate 330 having gas passage 340 formed thereon. One end of passage 340 is fluidly coupled to gas inlet 310 and its opposite end fluidly coupled to gas outlet 320 such that gas entering heater 300 traverses the length of passage 340 and the heater 300 through outlet 320. As illustrated in FIG. 3, in some embodiments, passage 330 may have serpentine (convoluted, tortuous, etc.) structure that increases path length, or soak length, of gas through heater 300. Increasing soak length of gas in heater 300 ensures that the entire volume of gas flowing through heater 300 is uniformly heated to desired temperature. Increased soak length may enable large flow rates of gas to be uniformly heated to high temperature (e.g., 550° C., 650° C., etc.) using heater 300. In general, the length of passage 330 in base plate 330 may depend on the application. In some embodiments, length of passage 330 in base plate 330 may be between about 150-250 inches. In some embodiments, path length may be between about 175-225 inches, while in some embodiments, path length may be between about 190-210 inches.

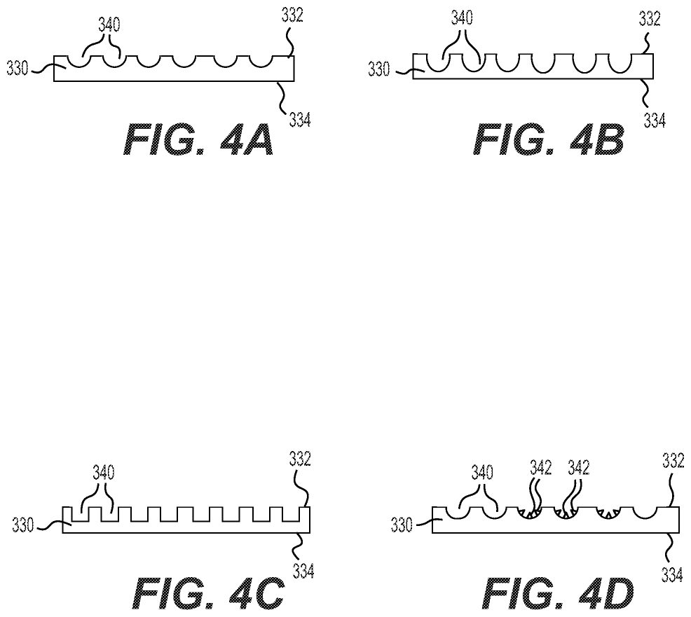

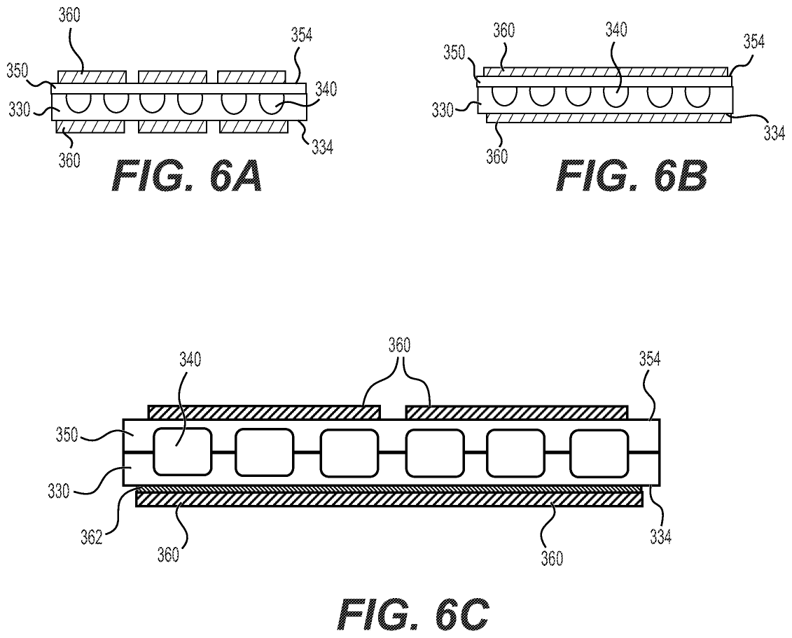

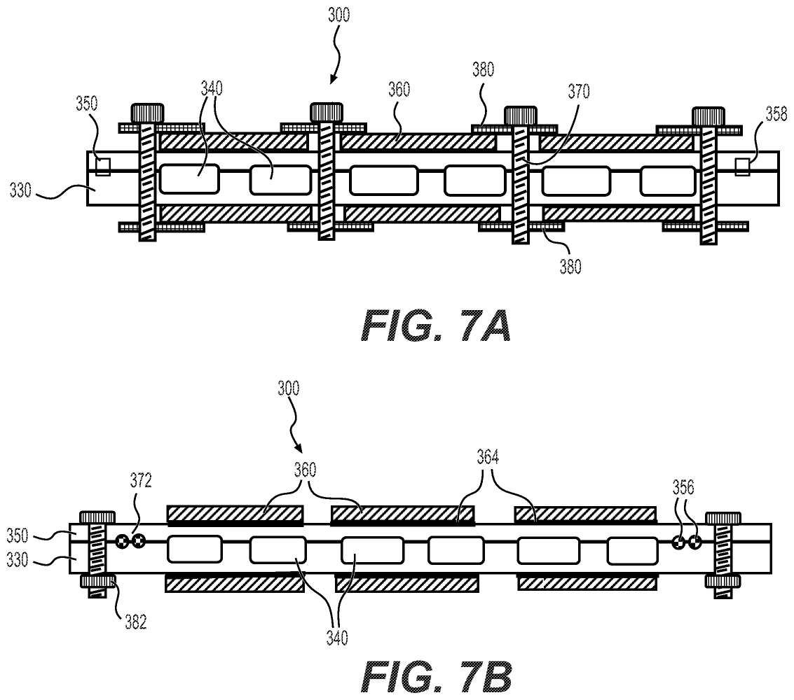

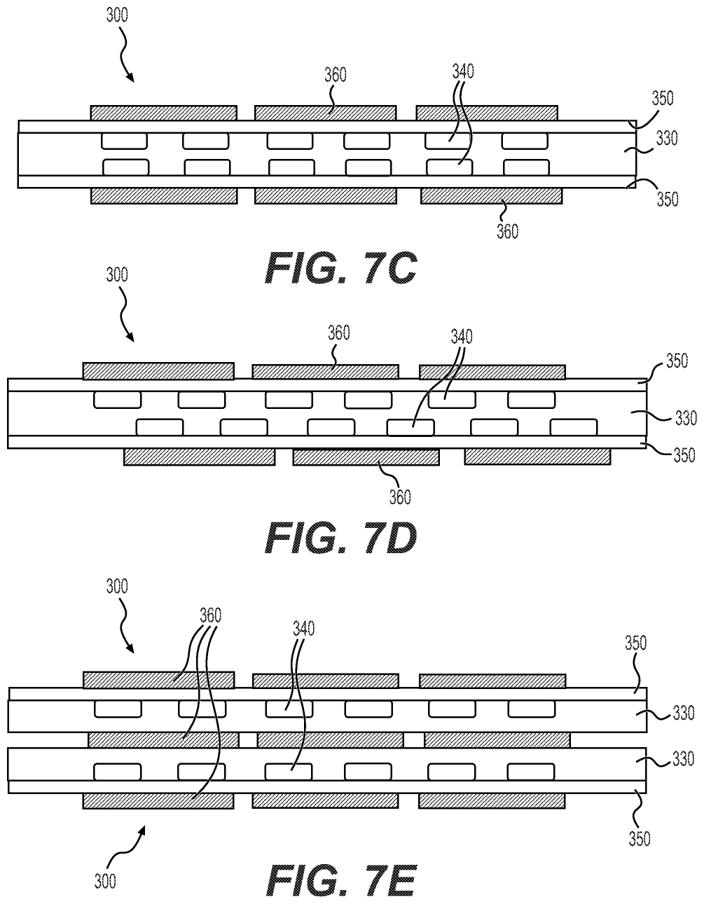

Passage 340 may be formed on base plate 330 in any known manner (e.g., machined, etc.). In some embodiments, as illustrated in FIG. 3, passage 340 may include a groove (or channel) formed on one surface (e.g., a first surface 332) of base plate 330 such that it is open or exposed on first surface 332 and not exposed on second surface 334 of base plate 330 opposite first surface 332. Cross-sectional shape and area of passage 340 on base plate 330 may be configured to increase the flow of gas therethrough. In some embodiments, as illustrate in FIG. 4A, passage 330 may have a substantially semi-circular cross-sectional shape. However, a semi-circular cross-sectional shape is not required. In some embodiments, as illustrated in FIGS. 4B, passage 340 may have substantially U-shaped cross-sectional shape, or substantially rectangular or square cross-sectional shape as illustrated in FIG. 4C (see also FIGS. 6C, 7A, and 7B). These cross-sectional shapes are merely exemplary and passage 340 may have any suitable cross-sectional shape. In some embodiments, width of slot that forms passage 340 may be between about 0.2-0.6 inches, and its depth may be between about 0.2-0.8 inches.

In some embodiments, inner surface of passage 340 may be substantially smooth. In some embodiments, as illustrated in FIG. 4D, inner surfaces of passage 340 may be roughened or include features 342 that protrude into passage 340 (e.g., into gas flow path). Protruding features 342 may assist to increase the transfer of heat from body of base plate 330 to gas flowing through passage 330. Protruding features 342 may be formed by any suitable process. For example, by machining grooves on inner surface such that their peaks project into passage 330, depositing particles of heat conducting material on inner surface, or machining fins on the inner surface, etc.

Base plate 330 may have any thickness. Typically, thickness of base plate 330 may depend on depth of passage 340 in base plate 330 and the contemplated use of heater 300. Increasing the thickness of base plate 330 may increase the structural rigidity and heat retention capacity of base plate 330. Optimizing the thickness of base plate 330 between bottom of passage 340 and second surface 334 may enable more efficient heat transfer from heaters 360 (see FIG. 3) to gas flowing through passage 330. In some embodiments, base plate 330 may have a thickness between about 0.2-1.5 inches, or between about 0.4-1 inch, or between about 0.4-0.8 inch.

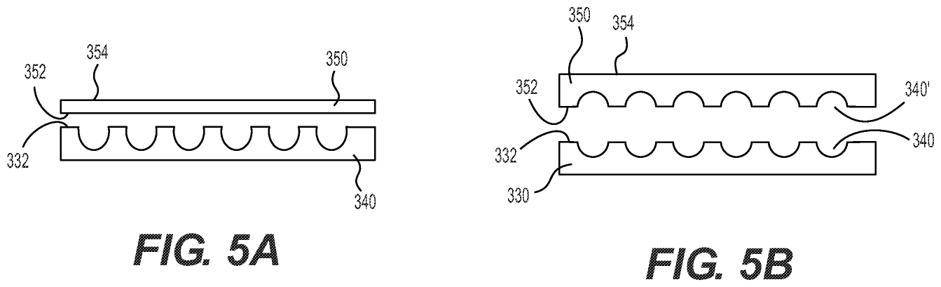

Referring to FIG. 3, cover plate 350 may be disposed on first surface 332 of base plate 330 to cover and enclose passage 340 therebetween. In some embodiments, cover plate 350 may be attached (e.g., brazed, etc.) to base plate 330. With cover plate 350 attached to base plate 330, passage 340 defines gas-flow conduit between inlet 310 and outlet 320. In some embodiments, as illustrated in FIG. 5A, surface (first surface 352) of cover plate 350 that engages with first surface 332 of base plate 330 may be substantially flat. In some embodiments, as illustrated in FIG. 5B, mating first surface 352 of cover plate 350 may also include passage 340′ (e.g., having a configuration similar to passage 340 of base plate 330) that mates with passage 340 of base plate 330 and collectively define gas-flow conduit between inlet 310 and outlet 320. In some embodiments, as shown in FIG. 7B, one or more gaskets 356 may be disposed between first surfaces 332, 352 to reduce the possibility of gas leaks from passage 340. Gaskets 356 may be arranged in any manner around passage 340. In some embodiments, as discussed with reference to FIG. 4D, inner surface of passage 340′ may also include features (e.g., similar to protruding features 342) configured to increase heat transfer from cover plate 350 to gas. Similar to base plate 330, cover plate 350 may also have any thickness. Although not a requirement, in some embodiments, the thickness of cover plate 350 may be between about 0.125-0.25 inches. In some embodiments, the thickness of cover plate 350, and the thickness of the channel base, may be optimized to speed heat transfer (increase heat flow rate) while providing a suitable margin against rupture (e.g., due to differential pressure between inside and outside of channel).

With reference to FIG. 3 and FIGS. 6A-6C, one or more heating elements 360 may be disposed on the surfaces of base plate 330 and cover plate 350 opposite passage 340. In other words, one or more heating elements 360 may be disposed on second surfaces 334 and 354 of base plate 330 and cover plate 350. In some embodiments, as illustrated in FIGS. 6A and 6B, the same number of heating elements 360 may be disposed on second surface 334 of base plate 330 and second surface 354 of cover plate 350. Any number of heating elements 360 (e.g., between 1-10) may be disposed on each of second surfaces 334, 354. In some embodiments, between 2-6 heating elements 360 may be disposed on each of second surfaces 334, 354. In some embodiments, heating elements 360 may be substantially equally spaced apart on second surfaces 334, 354. In some embodiments, as illustrated in FIG. 6C, a different number of heating elements 360 may be disposed on second surface 334 of base plate 330 and second surface 354 of cover plate 350. In some embodiments, heating elements 360 may be pressed against surfaces of base and cover plates 330, 350 without any intervening material therebetween. In some embodiments, as illustrated in FIG. 6C, a thermal interface material (e.g., thermal grease, thermal pad, epoxy, etc.) may be disposed between heating elements 360 and surface of the base plate 330 and/or cover plate 350 to improve heat transfer therebetween.

In some embodiments, heating elements 360 may be any type of commercially available heating element. Although not a requirement, typically heating elements 360 produces heat by converting electrical energy to heat (such as, for example, a resistance heater). In some embodiments, each heating element 360 may be plate-like resistance heater or mineral insulated (MI) heater. In some embodiment, heating elements 360 may include high-temperature co-fired ceramic (HTCC) heaters, ceramic insulated strip heaters, polyimide heaters, etc. Each heating element 360 may include any size and thickness. In some embodiments, as illustrated in FIG. 3, each heating element 360 used in heater 300 may have same size and thickness. However, as evident from FIG. 6C, this is not required.

The above-described components of heater 300 may be assembled together in any manner. In some exemplary embodiments, as illustrated in FIGS. 3 and 7A, base plate 330 and cover plate 350 may be attached together using braze joint 358, and heating elements 360 may be assembled on brazed assembly using screws 370 and clamps 380. For example, screws 370 may pass through clamps 380 arranged on second surfaces 334, 354 of base and cover plates 330, 350 to couple components together. For example, as schematically illustrated in FIG. 7A, screws 370 may pass through threaded clamps 380 and bores on base and cover plates 330, 350 to snugly couple components of heater 300 together. The above-described coupling technique is only exemplary and components of heater 300 may be coupled together in any suitable manner. For example, in some exemplary embodiments, as schematically illustrated in FIG. 7B, heaters 360 may attached to second surfaces 334, 354 of base and cover plates 330, 350 using a thermally conductive adhesive 364 (e.g., a conductive epoxy, etc.) and base and cover plates 330, 350 may be coupled together using screws 372 and nuts 382. In some embodiments, as shown in FIG. 7B, one or more O-rings may be disposed between the base and cover plates 330, 350 to minimize gas leaks.

The above-described configurations of heater 300 are merely exemplary. Heaters of the current disclosure may have many other configurations. For example, in some embodiments, as illustrated in FIGS. 7C and 7D, passages 340 may be formed on opposite sides of base plate 330. In other words, first passage 340 may be formed on one side of base plate 330 and second passage 340 may be formed on opposite side of base plate 330. First and second passages 340 may be configured to heat the same gas or different gases. For example, in some embodiments, both first and second passages 340 may be fluidly connected to same gas inlet 310 and gas outlet 320 (see FIG. 3) to pass the same gas through both passages 340. And in some embodiments, first and second passages 340 may be fluidly connected to different gas inlets and outlets to pass different gases through each passage. Cover plates 350 may be disposed on opposite sides of base plate 330 to enclose first and second passages 340 and define gas-flow conduits on opposite sides of base plate 330. Heaters 360 may be attached to side of each cover plate 350 opposite passages 340 to heat gas flowing through first and second passages 340. In some embodiments, as illustrated in FIG. 7C, first and second passages 340 on opposite sides of base plate 330 may be aligned (e.g., vertically aligned) such that both passages 340 traverse the same path on opposite sides of base plate 330. In some embodiments, as illustrated in FIG. 7D, first passage 340 and the second passage 340 may be staggered. In some embodiments, as illustrated in FIG. 7E, multiple heaters 300 may be stacked together to form heating system. Heaters of FIGS. 7C-7E may be assembled together in any manner. For example, heaters may be assembled together as depicted in FIG. 7A or 7B, or in any other manner.

The components of above-described heaters 300 may be fabricated using any suitable material. For example, in some embodiments, base and cover plates 330, 350 may be made of a thermally conductive material such as, for example, stainless steel, aluminum, etc. It is also contemplated that, in some embodiments, one or both of base plate 330 and cover plate 350 may be made of a thermally conductive ceramic or plastic material. In some embodiments, the screws 370, 372 and clamps 380 used to couple the components of the heater together may be formed of a similar material to reduce the coefficient of thermal expansion (CTE) mismatch induced stresses in the components.

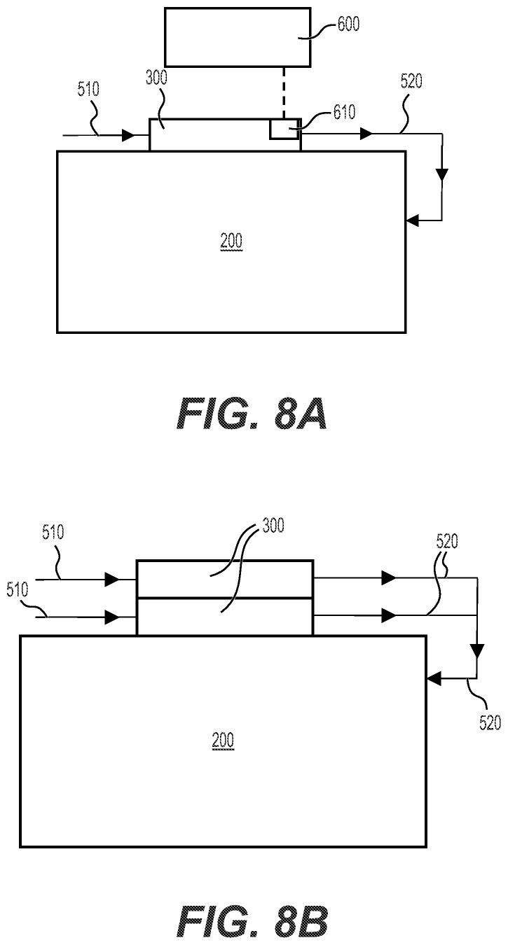

FIGS. 8A and 8B illustrate exemplary applications of disclosed heater 300. In some embodiments, as illustrated in FIG. 8A, gas flow 510 may be directed into heater 300 and heated gas flow 520 from heater 300 may be directed into processing chamber 200. In some embodiments, heater 300 may be coupled to wall of processing chamber 200. As illustrated in FIG. 8A, in some embodiments, heater 300 may include one or more thermocouples 610 configured to detect temperature of heater 300 (e.g., the temperature of the heated gas flow 520). Control system 600 (e.g., controller of oven 100, see FIGS. 1A, 1B) may control the operation of heater 300 based on signals from thermocouples 610. For example, control system 600 may increase or decrease (i.e., control) electric current directed to heating elements 360 of heater 300 to increase or decrease temperature of heating elements 360 and thereby control temperature of output gas flow 520. Additionally, or alternatively, in some embodiments, control system 600 may control rate of gas flow through heater 300 to control temperature of heated gas flow 520. In some embodiments, control system 600 may control heater 300 using feedback loop. In some embodiments, as illustrated in FIG. 8B, multiple heaters 300 may be stacked together in an application. Stacked heaters 300 may be fluidly connected together in parallel (as shown in FIG. 8B) or may be connected together in series.

Although heaters 300 of the current disclosure are described as being used to heat gases directed to processing chamber 200, persons of ordinary skill in the art would recognize that the disclosed heaters can be used for any application. Furthermore, although in the description above, some features were disclosed with reference to specific embodiments, a person skilled in the art would recognize that this is only exemplary, and the features are applicable to all disclosed embodiments. Other embodiments of the heater, its features and components, and related methods will be apparent to those skilled in the art from consideration of the disclosure herein.

What is claimed is:

1. A heating unit, comprising:
a base plate having a first side and a second side opposite the first side, wherein the base plate includes a passage extending therethrough, the passage being open on the first side and closed on the second side;
a cover plate having a third side and a fourth side opposite the third side, wherein the cover plate is disposed on the base plate such that the third side and the passage together define a conduit extending through the base plate;
a first set of heaters disposed on the second side of the base plate, wherein the first set of heaters includes one or more heaters; and
a second set of heaters disposed on the fourth side of the cover plate, wherein the second set of heaters includes one or more heaters.

2. The heating unit of claim 1, wherein the first set of heaters includes multiple heaters spaced-apart on the second side of the base plate.

3. The heating unit of claim 1, wherein the second set of heaters includes multiple heaters spaced-apart on the fourth side of the cover plate.

4. The heating unit of claim 1, wherein the first set of heaters and the second set of heaters include a same number of heaters.

5. The heating unit of claim 1, wherein the passage is fluidly coupled to a gas inlet at one end and fluidly coupled to a gas outlet at an opposite end, wherein the gas inlet is configured to admit a gas into the conduit and the gas outlet is configured to discharge the gas from the conduit.

6. The heating unit of claim 5, wherein the passage is a serpentine passage.

7. The heating unit of claim 1, wherein the passage is a machined cavity extending on the first side of the base plate.

8. The heating unit of claim 1, wherein the cover plate is brazed to the base plate.

9. The heating unit of claim 1, wherein each heater of the first and second sets of heaters are resistance heaters.

10. The heating unit of claim 1, wherein the first set of heaters and the second set of heaters include multiple symmetrically arranged heaters.

11. The heating unit of claim 1, wherein a cross-sectional shape of the passage is one of substantially semi-circular, substantially U-shaped, substantially rectangular, or substantially square.

12. A heating unit, comprising:
a base plate having a first side and a second side opposite the first side;
a cover plate having a third side and a fourth side opposite the third side, wherein the third side of the cover plate is disposed on the first side of the base plate;
a gas-flow conduit defined by the base plate and the third side of the cover plate;
a gas inlet fluidly coupled to a first end of the gas-flow conduit, the gas inlet being configured to admit a gas into the gas-flow conduit;
a gas outlet fluidly coupled to a second end of the gas-flow conduit, the gas outlet being configured to discharge a gas from the gas-flow conduit;
a first set of heaters configured to heat the second side of the base plate, wherein the first set of heaters includes one or more heaters; and
a second set of heaters configured to heat the fourth side of the cover plate, wherein the second set of heaters includes one or more heaters.

13. The heating unit of claim 12, wherein the gas-flow conduit includes a passage extending between the first end and the second end machined on the first side of the base plate.

14. The heating unit of claim 13, wherein the passage extends in a serpentine manner between the first end and the second end.

15. The heating unit of claim 12, wherein the first set of heaters includes multiple spaced-apart heaters and the second set of heaters include multiple spaced-apart heaters.

16. The heating unit of claim 15, wherein the first set of heaters and the second set of heaters include a same number of heaters, and the same number is between 2 and 6.

17. The heating unit of claim 12, wherein the first set of heaters is removably coupled to the second side of the base plate.

18. The heating unit of claim 12, wherein the first set of heaters is attached to the second side of the base plate using a conductive adhesive.

19. The heating unit of claim 12, wherein the heaters of the first set and the second set include resistance heaters.

20. The heating unit of claim 12, wherein the cover plate is brazed to the base plate.
